(19) United States
(12) Patent Application Publication
(10) Pub. No.: US 2019/0187179 A1
(43) Pub. Date: Jun. 20, 2019

(54) Portable Electrical Testing Device with Electrical Probe and Laser Soldering Device

(71) Applicant: International Business Machines Corporation, Armonk, NY (US)

(72) Inventors: Alberto Garza, Austin, TX (US); David L. Green, Austin, TX (US); Emile L. Kowalski, Austin, TX (US); Joel Ruiz, Austin, TX (US)

(21) Appl. No.: 15/843,626

(22) Filed: Dec. 15, 2017

(51) Int. Cl. G01R 1/067; G01R 31/28

(52) U.S. Cl. CPC G01R 1/06755; G01R 31/2886

(57) ABSTRACT

A portable electrical testing device is disclosed. The portable electrical testing device includes an electrical probe and a laser soldering device. The electrical probe is configured to be placed in contact with an electrical circuit element and to receive electrical signals from the circuit element. The laser soldering device is configured to apply laser radiation to the electrical probe while the probe is in contact with the electrical circuit element to heat the electrical probe and to thereby enable soldering of the electrical probe to the electrical circuit element. The electrical probe further includes a replaceable probe lead having a surface coating of an electrically conductive fusible metal alloy that melts, when heated by laser radiation from the laser soldering device, and forms a mechanical bond with the circuit element upon cooling. The electrical probe and laser soldering device are configured to be adjustably positioned relative to a mechanical housing.

### BACKGROUND

This disclosure generally relates to electrical testing probes for testing electronic circuits, and particularly, to improved testing probes that enable efficient soldering of a probe to a location in an electrical circuit.

Commercially generated electrical circuits are generally subjected to electrical testing to ensure quality and reliability of the circuit. Conventionally, testing of electrical circuits on printed circuit boards (PCB) may be performed using browser-style or solder-in probes. Browser probes allow engineers to quickly measure electrical signals in specific locations in a circuit by contacting a probe tip to a desired location in the circuit and by applying mechanical pressure to the probe tip to ensure a good electrical connection is made between the probe tip and the electrical circuit. Such hand-held probes, however, are not ideal for measurements that require the probe to be held in place for a significant amount of time or for measurements in hard-to-reach locations of the circuit in question.

In such circumstances, solder-in probes may be used because they allow the person carrying out a testing procedure to simply solder the probe in place before the measurement is performed. A disadvantage of conventional solder-in probes is that, generally, the device under test (DUT) often is required to be powered off when attaching the solder-in probe. For a system that requires several verification measurements, soldering and de-soldering probes to and from various locations within a PCB is a time-consuming and error-prone process.

### SUMMARY

The disclosed embodiments overcome several drawbacks associated with conventional electrical testing probes by using laser radiation to efficiently solder and de-solder test probes, thereby significantly reducing time required to perform electrical measurements of electrical circuits.

In this regard, a portable electrical testing device is disclosed. The portable electrical testing device includes an electrical probe and a laser soldering device. The electrical probe is configured to be placed in contact with an electrical circuit element and to receive electrical signals from the circuit element. The laser soldering device is configured to apply laser radiation to the electrical probe while the probe is in contact with the electrical circuit element. The applied laser radiation heats the electrical probe and enables soldering of the electrical probe to the electrical circuit element to thereby form a mechanical bond between the electrical probe and the circuit element.

The electrical probe may further include a surface coating of an electrically conductive fusible metal alloy. The electrically conductive fusible metal alloy is configured to be heated by receiving radiation from the laser soldering device and to thereby be melted, when the electrical probe is in contact with the electrical circuit element. Upon cooling in the absence of radiation from the laser, the electrically conductive fusible metal alloy is configured to solidify and to thereby form a mechanical bond between the electrical probe and the circuit element. The electrical probe may further include a replaceable probe lead including the electrically conductive fusible metal alloy as a surface coating.

The portable electrical testing device may further include an electrical sensor that determines when the electrical probe is in electrical contact with an electrical circuit element. The portable electrical testing device may further include a safety mechanism that enables operation of the laser soldering device only when the electrical probe is determined by the sensor to be in contact with the electrical circuit element. The portable electrical testing device may further include a pressure sensor that determines when a pressure is applied between the electrical probe and the electrical circuit element. A further safety mechanism may enable operation of the laser soldering device only after a predetermined time duration during which the electrical probe has been in electrical contact with the electrical circuit element, and pressure has been applied between the electrical probe and the electrical circuit element.

The portable electrical testing device may further include an accelerometer that determines three-dimensional accelerations of the electrical probe. A further safety mechanism may enable operation of the laser soldering device only when accelerations of the electrical probe are determined by the accelerometer to be below a predetermined threshold.

A method of operating a portable electrical testing device is also disclosed. The method includes placing an electrical probe of the portable electrical testing device in contact with an electrical circuit element. The method further includes activating a laser soldering device of the portable electrical testing device to cause laser radiation to be transmitted to and to be received by the electrical probe while the probe is in contact with the electrical circuit element. The laser radiation received from the laser soldering device heats the electrical probe and enables soldering of the electrical probe to the electrical circuit element thereby forming a mechanical bond between the electrical probe and the circuit element.

The method may further include causing the laser radiation to be transmitted to and to be received by a replaceable probe lead on the electrical probe that includes a surface coating of an electrically conductive fusible metal alloy. The surface coating of an electrically conductive fusible metal alloy then melts upon heating from laser radiation received from the laser soldering device and flows to thereby make simultaneous contact with the electrical circuit element and the electrical probe. Upon cooling in the absence of laser radiation, the electrically conductive fusible metal alloy solidifies to form the mechanical bond between the electrical probe and the circuit element.

Further embodiments, features, and advantages, as well as the structure and operation of the various embodiments, are described in detail below with reference to the accompanying drawings.

### BRIEF DESCRIPTION OF THE DRAWINGS

The accompanying drawings, which are incorporated in and constitute a part of this specification, illustrate various embodiments of the invention and, together with the general description of the invention given above, and the detailed description of the embodiments given below, explain the embodiments of the invention. In the drawings, like reference numbers generally indicate identical, functionally similar, and/or structurally similar elements.

FIG. 1 is a schematic illustration of a portable electrical testing device that includes electrical probes and corresponding laser soldering devices, according to an embodiment.

FIG. 1A provides a detailed view of the first probe, the second probe, the first adjustable mounting device, and the second adjustable mounting device, of FIG. 1, according to an embodiment.

FIG. 2 is a schematic illustration of the first and second probes of FIG. 1, which each contain an electrical probe and corresponding laser soldering device, according to an embodiment.

FIG. 3 is a schematic illustration of an electrical probe having internal circuitry including various sensors and safety mechanisms, according to an embodiment.

FIG. 4 is flowchart providing an overview of a method of using a portable electrical testing device, according to an embodiment.

FIG. 5 is flowchart illustrating further details of a method of using a portable electrical testing device, according to an embodiment.

### DETAILED DESCRIPTION

This disclosure provides electrical testing probes that may be soldered in place within a circuit using a portable, hand-held, electrical testing device that includes an electrical probe and a laser soldering device integrated within a single apparatus. The disclosed electrical testing device applies laser radiation to heat an isolated area within contact of an electrical probe or to a nearby region, and feeds solder to join the electrical probe to a point of contact within an electrical circuit to be tested. The disclosed embodiments: eliminate the use of separate tools for soldering and electrical testing, reduce the need to transport the device under test (DUT), and reduce time spent in configuring the DUT for testing, thereby providing a more efficient probing technique.

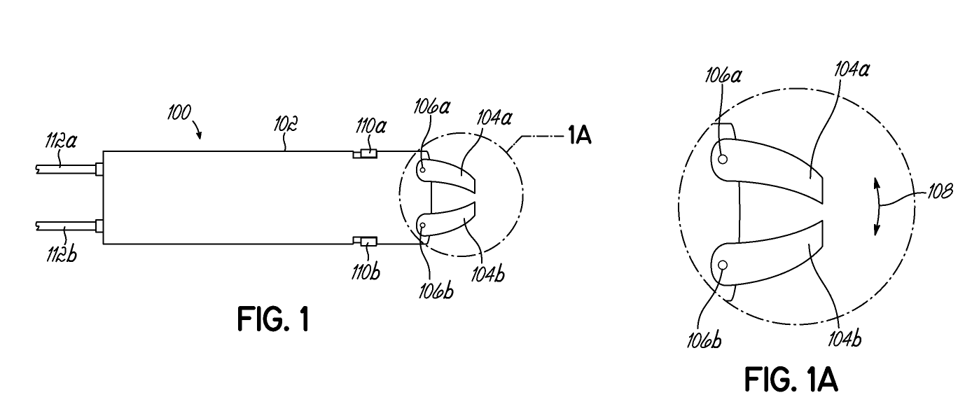

FIG. 1 is a schematic illustration of a portable electrical testing device 100 that includes electrical probes and corresponding laser soldering devices, according to an embodiment. The portable electrical testing device 100 may have a body 102 that provides a mechanical housing for one or more electrical testing probes. In this example, the portable electrical testing device 100 includes a first probe 104a and a second probe 104b. The first probe 104a may be mounted to the mechanical housing 102 with a first adjustable mounting device 106a. The second probe 104b may be mounted to the mechanical housing 102 with a second adjustable mounting device 106b. The adjustable mounting devices, 106a and 106b, may mount the electrical probes to the mechanical housing 102 in a way that enables the first 104a and second 104b probes to be adjustably positioned relative to the mechanical housing 102.

FIG. 1A provides a detailed view of the first probe 104a, the second probe 104b, the first adjustable mounting device 106a, and the second adjustable mounting device 106b. In this example, the adjustable mounting devices, 106a and 106b, allow the first probe 104a and the second probe 104b to be adjustably positioned in a plane parallel to the plane of FIGS. 1 and 1A. As shown, the first adjustable mounting device 106a and the second adjustable mounting device 106b enable an angular displacement 108 of the first 104a probe relative to the second 104b. In certain embodiments, the first probe 104a may be adjustably positioned independently of the second probe 104b. For example, the first probe 104a may be positioned according to an angular displacement 108 while the second probe 104b is held fixed. Similarly, the second probe 104b may be positioned with an angular displacement 108 while the first probe 104a is held fixed.

In further embodiments, the first 104a and second 104b probes may be positioned according to an angular displacement 108 in a concerted fashion. For example, the first 104a and second 104b probes may move toward one another with an angular displacement 108. In a further example, the first 104a and second 104b probes may move away from one another with an angular displacement 108.

The portable electrical testing device 100 may further include a first mechanical adjustment device 110a that may be adjusted by a user. Adjustment of the first mechanical adjustment device 110a may impart a mechanical displacement to the first probe 104a. Similarly, portable electrical testing device 100 may further include a second mechanical adjustment device 110b that may be adjusted by a user. Adjustment of the second mechanical adjustment device 110b may impart a mechanical displacement to the second probe 104b. For example, the first 110a and second 110b mechanical adjustment devices may include a knob, a lever, or other mechanical actuator.

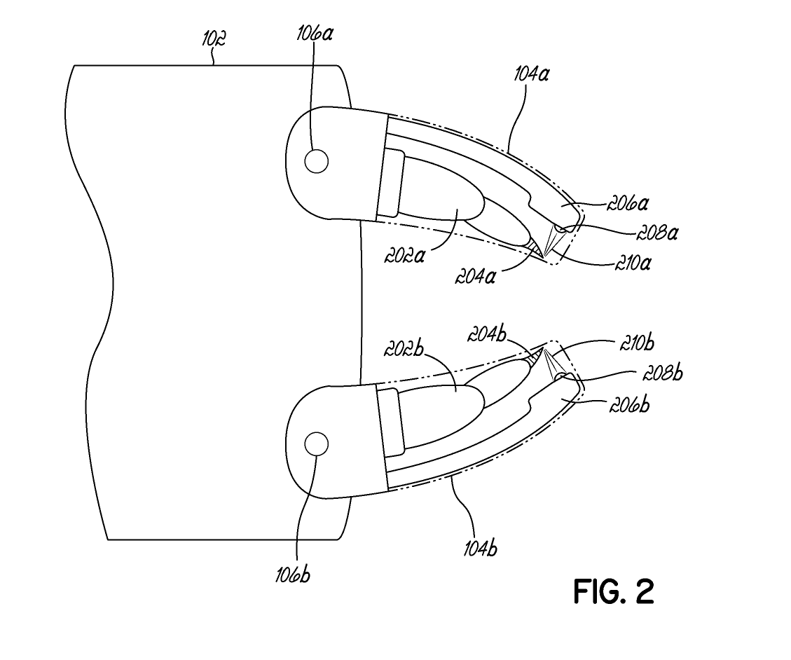

As described in greater detail below (with reference to FIG. 2), the first 104a and second 104b probes are composite structures containing an electrical probe 202 and corresponding laser soldering device 206. The electrical probe 202 is configured to be placed in contact with an electrical circuit element and is configured to receive electrical signals from the circuit element. The portable electrical testing device 100 further includes a first electrical lead 112a and a second electrical lead 112b. First 112a and second 112b electrical leads receive electrical signals from the first 104a and second 104b probes and provided the received signals to an external measurement device (not shown). The external measurement device may be a voltage meter, a current meter, an oscilloscope, etc. The composite structures of probes 104a and 104, each containing an electrical probe 202 and corresponding laser soldering device 206, are described in greater detail below with reference to FIG. 2.

FIG. 2 is a schematic illustration of the first 104a and second 104b probes of FIG. 1, which each contain an electrical probe 202 and corresponding laser soldering device 206, according to an embodiment.

The first probe 104a includes an electrical probe 202a with an electrically conducting tip 204a. Similarly, the second probe 104b includes an electrical probe 202b with an electrically conducting tip 204b. The first probe 104a includes a laser soldering device 206a, with a lens 208a, that provides laser radiation 210a to the electrically conducting tip 204a. Similarly, the second probe 104b includes a laser soldering device 206b, with a lens 208b, that provides laser radiation 210b to the electrically conducting tip 204b. The laser radiation, 210a and 210b, projected respectively by laser soldering devices, 206a and 206b, provides heat to electrically conducting tips, 204a and 204b, respectively. The laser radiation, 210a and 210b, received by electrically conducting tips, 204a and 204b, causes the electrically conducting tips, 204a and 204b, to be heated sufficiently to enable soldering of the electrically conducting tips, 204a and 204b, to desired locations within an electrical circuit to be tested.

According to an embodiment, each of electrically conducting tips, 204a and 204b, may be provided with a surface coating of an electrically conductive fusible metal alloy (not shown). The fusible metal alloy on each of the electrically conducting tips, 204a and 204b, may be configured to be heated by receiving radiation from a respective laser soldering device, 206a and 206b, and to thereby be melted, when the respective electrical probe tips, 204a and 204b, are in contact with corresponding electrical circuit elements to be tested. The fusible metal alloy on each of the electrically conducting tips, 204a and 204b, may be further configured to solidify and thereby form a mechanical bond between the electrically conducting tips, 204a and 204b, and the corresponding circuit elements upon cooling in the absence of radiation from respective laser soldering devices, 206a and 206b.

As described above, a mechanical housing 102 is provided which physically supports the first 104a and second 104b probes. Each of first 104a and second 104b probes may be provided with respective first 106a and second 106b adjustable mounting devices that enable the first 104a and second 104b probes to be adjustably positioned relative to the mechanical housing 102. In a further embodiment, each of the adjustable mounting devices, 106a and 106b, enable the electrical probes, 202a and 202b, and the laser soldering devices, 206a and 206b, to be adjustably positioned relative to the mechanical housing 102.

In a further embodiment, the adjustable mounting devices, 106a and 106b, enable the electrical probes, 202a and 202b, and the laser soldering devices, 206a and 206b, to be adjustably positioned relative to the mechanical housing 102 while maintaining a fixed positional relative orientation between each of the electrical probes, 202a and 202b, and each respective laser soldering device, 206a and 206b.

The embodiments described above refer to embodiments in which the mechanical housing 102 supports two probes, 104a and 104b. Other embodiments, however, may have only a single probe with corresponding electrical probe and laser soldering device. Still further embodiments may include one or more additional electrical probes with one or more corresponding laser soldering devices mounted to a mechanical housing using adjustable mounting devices. Further, the adjustable mounting devices may enable the one or more additional electrical probes and the one or more corresponding laser soldering devices to be adjustably positioned relative to the mechanical housing.

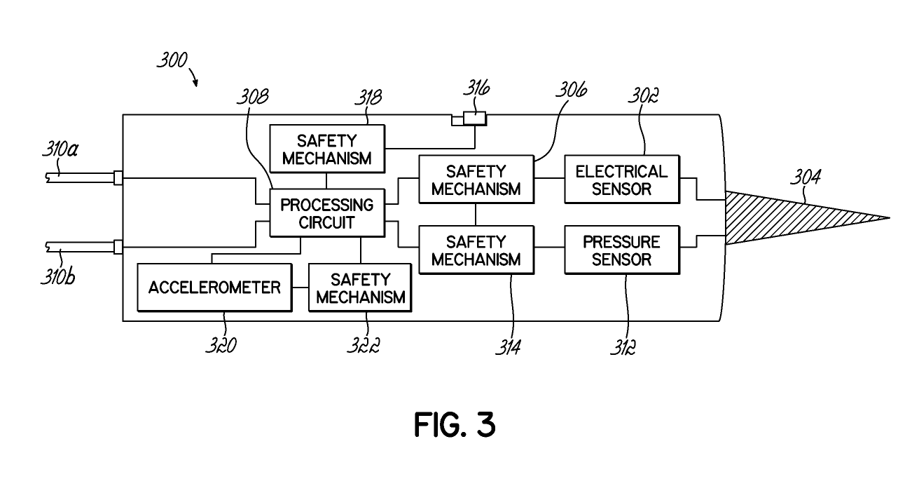

FIG. 3 is a schematic illustration of an electrical probe 300 having internal circuitry including various sensors and safety mechanisms, according to an embodiment. Electrical probe 300 may be similar to probes 202a and 202b discussed above. Electrical probe 300 may include an electrical sensor 302 that determines when an electrically conducting probe tip 304 of the electrical probe 300 is in electrical contact with an electrical circuit element (not shown). Electrical probe 300 may further include a safety mechanism 306 that enables operation of the laser soldering device (not shown in this figure) only when the electrical probe tip 304 of the electrical probe 300 is determined by the sensor 302 to be in contact with the electrical circuit element. Electrical probe 300 may further include a processing circuit 308 that receives an electrical control signal from the safety mechanism 306. Based on a value of the electrical control signal received from the safety mechanism 306, the processing circuit 308 may control transmission of electrical signals received from the electrically conductive probe tip 304 to external leads 310a and 310b.

In a further embodiment, electrical probe 300 may further include a pressure sensor 312 that determines when a pressure is applied between the electrically conducting probe tip 304 of the electrical probe 300 and the electrical circuit element. Electrical probe 300 may further include a safety mechanism 314 that enables operation of the laser soldering device (not shown) only if certain conditions have been met. The safety mechanism 314 may communicate with safety mechanism 306 and may provide electrical control signals to the processing circuit 308. In this regard, safety mechanism 314 may only enable operation of electrical probe 300 after a predetermined time duration during which: (1) the electrically conducting probe tip 304 of the electrical probe 300 has been in electrical contact with the electrical circuit element, as determined by the sensor 302, and (2) during which pressure has been applied between the electrically conducting probe tip 304 the electrical probe 300 and the electrical circuit element, as determined by the pressure sensor 312.

The processing circuit 308 may be configured to receive an electrical control signal from the safety mechanism 314 in addition to safety mechanism 306. Further, based on a value of the electrical control signal received from the safety mechanisms 306 and 314, the processing circuit 308 may control transmission of electrical signals received from the electrically conductive probe tip 304 to external leads 310a and 310b.

In a further embodiment, electrical probe 300 may further include a laser activation device 316. The laser activation device 316 may be a switch or other electro-mechanical device that receives input from a user and generates an activation signal. The laser activation device 316 may be a conventional electro-mechanical switch that is activated by receiving a mechanical stimulus from a user. In further embodiments, laser activation device 316 may an optical or electrical device that detects a user's touch. For example, laser activation device 316 may be a touch sensor that generates a signal in response to detecting a user's touch. Electrical probe 300 may further include a safety mechanism 318 that enables operation of the laser soldering device only for a predetermined time duration after the laser activation device 316 has received input from a user and generated a signal that is provided to safety mechanism 318.

The processing circuit 308 may be configured to receive an electrical control signal from the safety mechanism 318 in response to receiving an activation signal from the laser activation device 316. Further, based on a value of the electrical control signal received from the safety mechanism 318, the processing circuit 308 may control transmission of electrical signals received from the electrically conductive probe tip 304 to external leads 310a and 310b.

According to an embodiment, electrical probe 300 may further include an accelerometer 320 that determines three-dimensional accelerations of the electrical probe 300. Electrical probe 300 may further include a safety mechanism 322 that enables operation of the laser soldering device only when accelerations of the electrical probe are determined by the accelerometer 320 to be below a predetermined threshold.

The processing circuit 308 may be configured to receive an electrical control signal from the accelerometer 320 and/or from the safety mechanism 322 in response to accelerations of the electrical probe 300 that are detected by the accelerometer 320. Further, based on a value of the electrical control signal received from the safety mechanism 322, the processing circuit 308 may control transmission of electrical signals received from the electrically conductive probe tip 304 to external leads 310a and 310b.

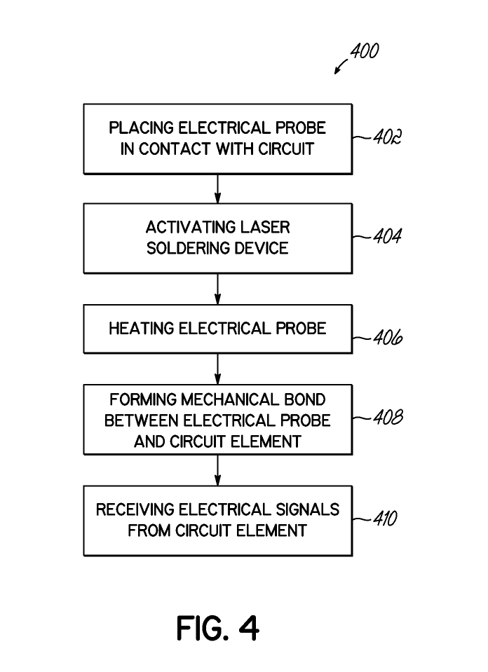

FIG. 4 is flowchart 400 providing an overview of a method of using a portable electrical testing device such as those illustrated in FIGS. 1 and 2, according to an embodiment.

In stage 402, the method includes placing an electrical probe of the portable electrical testing device in contact with an electrical circuit element. In stage 404 the method includes activating a laser soldering device of the portable electrical testing device. This action causes laser radiation to be transmitted to, and to be received by, an electrical probe while the probe is in contact with the electrical circuit element. In stage 406, the method includes heating of the electrical probe by the received radiation which enables soldering of the electrical probe to the electrical circuit element. In stage 408, the method includes forming an electrical and mechanical bond between the electrical probe and the circuit element. This is achieved when the heated electrical probe causes solder to melt and to flow between the heated probe and the circuit element, and upon cooling, the solder solidifies to form an electrical and mechanical bond between the electrical probe and the circuit element. In stage 410, the method includes causing the electrical probe that has been mechanically bonded to the circuit element to receive electrical signals from the circuit element.

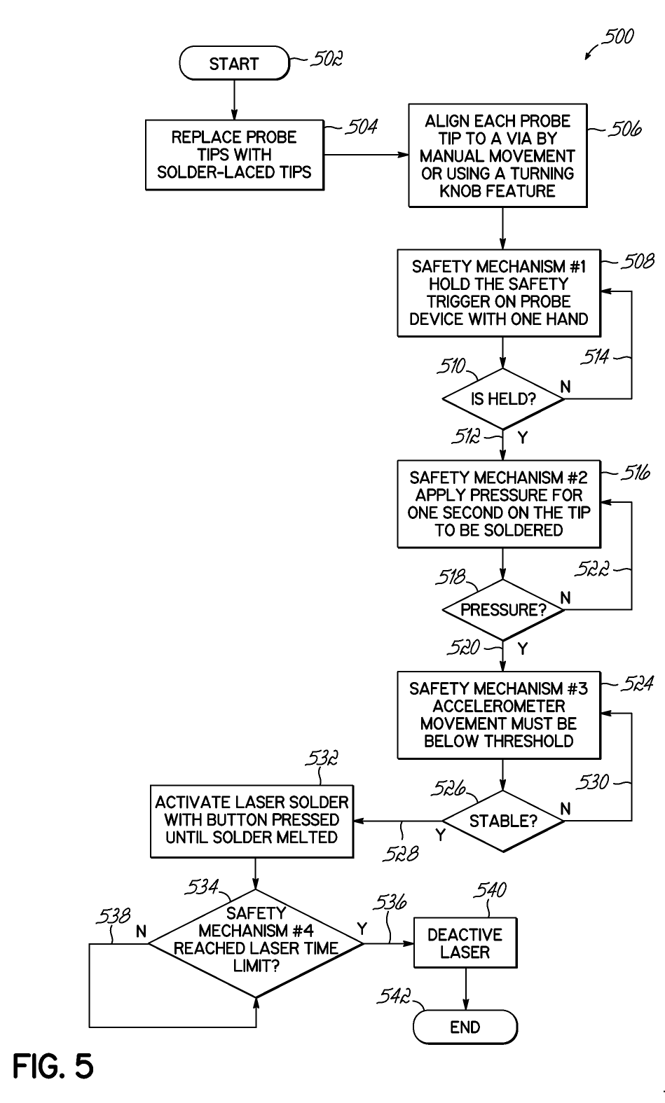

FIG. 5 is flowchart 500 illustrating further details of a method of using a portable electrical testing device, according to an embodiment. The method starts at stage 502. In stage 504, the method may include a replacing a probe tip 304 (see FIG. 3) that has a surface coating of the electrically conductive fusible metal alloy. Stage 506 may include aligning one or more probe tips (e.g., 304 of FIGS. 3, or 104a and 104b of FIGS. 1, 1A, and 2) to place the one or more probe tips in contact with a circuit element (or “via”). The probe tips may be positioned manually or by actuating one or more mechanical adjustment device (e.g. mechanical adjustment device 110a and 110b of FIG. 1). As described above, the adjustable mounting devices may be configured to maintain a fixed positional relative orientation between each electrical probe (e.g., 204a and 204b) and corresponding laser soldering device (e.g., 206a and 206b).

In stage 508, the method includes invoking a safety mechanism to only activate the laser soldering device if a safety trigger is engaged (e.g., laser activation device 316 of FIG. 3). In stage 510, the method includes determining whether the safety trigger has been engaged. In stage 512, upon determining that the safety trigger is engaged, the method proceeds to stage 516. In stage 512, when the safety trigger is determined to not be engaged, the method returns to stage 508.

In stage 516, a pressure sensor may determine that a pressure is applied between the electrical probe and the electrical circuit element for a predetermined time duration. In this example, the predetermined time duration may be one second. In other embodiments, the predetermined time duration may take on any other value as dictated by design choice. In stage 518, the method includes determining whether a pressure is applied between the electrical probe and the electrical circuit element. In stage 520, upon determining that a pressure is applied between the electrical probe and the electrical circuit element, the method proceeds to stage 524. In stage 522, when a pressure is determined to not be applied between the electrical probe and the electrical circuit element the method returns to stage 516.

In stage 524, an accelerometer may determine three-dimensional accelerations of the electrical probe. In stage 526, the method includes determining whether the electrical probe is being held in a stable condition. For example, in stage 528, when a measured acceleration is determined to be below a predetermined threshold, the method proceeds to stage 532. In stage 530, the method may include determining that accelerations are above a predetermined threshold and, therefore, that the electrical probe is not being held in a stable condition. In this situation, at stage 530, the method returns to stage 524.

At stage 532, the method includes activating the laser soldering device while the laser activation device 316 is activated (e.g., while a button is pressed) for a time sufficient to heat and thereby melt the electrically conductive fusible metal alloy (e.g., solder). In stage 534, the method may include determining whether the laser soldering device has been activated for a time greater than a predetermined time limit. In stage 536, the method may include determining that the predetermined time limit has been exceeded. In this situation, the method proceeds to stage 540 in which the laser soldering device is deactivated, thus ending the method in stage 542. In stage 538, the method may include determining that the predetermined time limit has not been exceeded. In this situation, the method may return to stage 534 with the laser soldering device continuing to be activated until predetermined time limit is exceeded in stage 536.

As described above, the method may further include other operations to ensure safety of operation. For example, an electrical sensor may be used to determining when the electrical probe is in electrical contact with an electrical circuit element. Further, the method may include enabling operation of the laser soldering device, by a safety mechanism, only when the electrical probe is determined by the sensor to be in contact with the electrical circuit element

The Summary and Abstract sections may set forth one or more but not all example embodiments and thus are not intended to limit the scope of embodiments of the invention and the appended claims in any way.

Embodiments have been described above with the aid of functional building blocks illustrating the implementation of specified functions and relationships thereof. The boundaries of these functional building blocks have been arbitrarily defined herein for the convenience of the description. Alternate boundaries can be defined to the extent that the specified functions and relationships thereof are appropriately performed.

The foregoing description of specific embodiments will so fully reveal the general nature of embodiments of the invention that others can, by applying knowledge of those of ordinary skill in the art, readily modify and/or adapt for various applications such specific embodiments, without undue experimentation, without departing from the general concept of embodiments of the invention. Therefore, such adaptation and modifications are intended to be within the meaning and range of equivalents of the disclosed embodiments, based on the teaching and guidance presented herein. It is to be understood that the phraseology or terminology herein is for description and not of limitation, such that the terminology or phraseology of the specification is to be interpreted by persons of ordinary skill in the relevant art considering the teachings and guidance presented herein.

The breadth and scope of embodiments of the invention should not be limited by any of the above-described example embodiments, but should be defined only in accordance with the following claims and their equivalents

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A portable electrical testing device, comprising:
an electrical probe configured to be placed in contact with an electrical circuit element and configured to receive electrical signals from the circuit element;
a laser soldering device configured to apply laser radiation to the electrical probe while the probe is in contact with the electrical circuit element to heat the electrical probe and to thereby enable soldering of the electrical probe to the electrical circuit element, to form a mechanical bond between the electrical probe and the circuit element.

2. The portable electrical testing device of claim 1, wherein the electrical probe further comprises:
a surface coating of an electrically conductive fusible metal alloy that is configured:
to be heated by receiving radiation from the laser soldering device and to thereby be melted, when the electrical probe is in contact with the electrical circuit element; and
upon cooling in the absence of radiation from the laser, to solidify and thereby form a mechanical bond between the electrical probe and the circuit element.

3. The portable electrical testing device of claim 2, wherein the electrical probe further comprises:
a replaceable probe lead comprising the surface coating of the electrically conductive fusible metal alloy.

4. The portable electrical testing device of claim 1, further comprising:
a mechanical housing that physically supports the electrical probe and laser soldering device;
adjustable mounting devices that mount the electrical probe and the laser soldering device to the mechanical housing,
wherein the adjustable mounting devices enable the electrical probe and the laser soldering device to be adjustably positioned relative to the mechanical housing.

5. The portable electrical testing device of claim 4, wherein the adjustable mounting devices are further configured:
to enable the electrical probe and the laser soldering device to be adjustably positioned relative to the mechanical housing while maintaining a fixed positional relative orientation between the electrical probe and the laser soldering device.

6. The portable electrical testing device of claim 4, further comprising:
one or more additional electrical probes with one or more corresponding laser soldering devices mounted to the mechanical housing using adjustable mounting devices that enable the one or more additional electrical probes and the one or more corresponding laser soldering devices to be adjustably positioned relative to the mechanical housing.

7. The portable electrical testing device of claim 1, further comprising:
an electrical sensor that determines when the electrical probe is in electrical contact with an electrical circuit element; and
a safety mechanism that enables operation of the laser soldering device only when the electrical probe is determined by the sensor to be in contact with the electrical circuit element.

8. The portable electrical testing device of claim 7, further comprising:
a pressure sensor that determines when a pressure is applied between the electrical probe and the electrical circuit element;
a safety mechanism that enables operation of the laser soldering device only after a predetermined time duration during which:
the electrical probe has been in electrical contact with the electrical circuit element; and
pressure has been applied between the electrical probe and the electrical circuit element.

9. The portable electrical testing device of claim 1, further comprising:
a laser activation device that activates the laser soldering device in response to input received from a user; and
a safety mechanism that enables operation of the laser soldering device only for a predetermined time duration after the laser soldering device has been activated by the laser activation device.

10. The portable electrical testing device of claim 1, further comprising:
an accelerometer that determines three-dimensional accelerations of the electrical probe; and
a safety mechanism that enables operation of the laser soldering device only when accelerations of the electrical probe are determined by the accelerometer to be below a predetermined threshold.

11. A method of operating a portable electrical testing device, comprising:
placing an electrical probe of the portable electrical testing device in contact with an electrical circuit element;
activating a laser soldering device of the portable electrical testing device to cause laser radiation to be transmitted to and to be received by the electrical probe while the probe is in contact with the electrical circuit element to heat the electrical probe and to thereby enable soldering of the electrical probe to the electrical circuit element, to form a mechanical bond between the electrical probe and the circuit element.

12. The method of claim 11, further comprising:
causing the electrical probe that has been mechanically bonded to the circuit element to receive electrical signals from the circuit element.

13. The method of claim 11, further comprising:
causing the laser radiation to be transmitted to and to be received by a surface coating of the electrical probe, the surface coating comprising an electrically conductive fusible metal alloy, to heat and thereby melt the electrically conductive fusible metal alloy;
causing the melted electrically conductive fusible metal alloy to flow to thereby make simultaneous contact with the electrical circuit element and the electrical probe;
de-activating the laser soldering device to discontinue transmission of the laser radiation to the electrical probe; and
allowing the conductive fusible metal alloy to cool and solidify, to thereby form the mechanical bond between the electrical probe and the circuit element.

14. The method of claim 11, further comprising:
causing the laser radiation to be transmitted to and to be received by a replaceable probe lead on the electrical probe,
wherein the replaceable probe lead comprises a surface coating of an electrically conductive fusible metal alloy that:
melts upon heating from laser radiation received from the laser soldering device;
flows to thereby make simultaneous contact with the electrical circuit element and the electrical probe; and
solidifies, upon cooling in the absence of laser radiation, to form the mechanical bond between the electrical probe and the circuit element.

15. The method of claim 11, further comprising:
adjusting the mechanical position of the electrical probe and the laser soldering device relative to a mechanical housing of the electrical testing device using adjustable mounting devices that mount the electrical probe and the laser soldering device to the mechanical housing.

16. The method of claim 15, further comprising:
adjusting the mechanical position of the electrical probe and the laser soldering device relative to the mechanical housing of the electrical testing device using the adjustable mounting devices that further maintain a fixed positional relative orientation between the electrical probe and the laser soldering device.

17. The method of claim 11, further comprising:
determining, by an electrical sensor, when the electrical probe is in electrical contact with an electrical circuit element; and
enabling operation of the laser soldering device, by a safety mechanism, only when the electrical probe is determined by the sensor to be in contact with the electrical circuit element.

18. The method of claim 17, further comprising:
determining, by a pressure sensor, that a pressure is applied between the electrical probe and the electrical circuit element;
enabling operation of the laser soldering device, by a safety mechanism, only after a predetermined time duration during which:
the electrical probe has been in electrical contact with the electrical circuit element; and
pressure has been applied between the electrical probe and the electrical circuit element.

19. The method of claim 11, further comprising:
receiving, by a laser activation device, input from a user;
activating the laser soldering device, by the laser activation device, in response to the input received from the user; and
enabling operation of the laser soldering device, by a safety mechanism, only for a predetermined time duration after the laser soldering device has been activated by the laser activation device.

20. The method of claim 11, further comprising:
determining, by an accelerometer, three-dimensional accelerations of the electrical probe; and
enabling, by a safety mechanism, operation of the laser soldering device only when accelerations of the electrical probe are determined by the accelerometer to be below a predetermined threshold.
